(19) United States
(12) Patent Application Publication
(10) Pub. No.: US 2024/0385955 A1
(43) Pub. Date: Nov. 21, 2024

(54) COMPUTER MEMORY

(71) Applicants: Stephen Furber, Derby (GB); Michael Hopkins, Wales (GB)

(72) Inventors: Stephen Byram Furber, Derby (GB); Michael Wynn Hopkins, Wales (GB)

(21) Appl. No.: 18/692,424

(22) PCT Filed: Sep. 16, 2022
(86) PCT No.: PCT/GB2022/052344

§ 371 Date: Mar. 15, 2024

(30) Foreign Application Priority Data
Sep. 17, 2021 (GB) 2113341.8

(51) Int. Cl. G06F 12/02; G06F 12/1009

(52) U.S. Cl. CPC G06F 12/0223; G06F 12/1009

(57) ABSTRACT

A computer memory apparatus is provided having a plurality of storage locations and a plurality of address decoder elements, each having a one or more input address connections for mapping to a respective one or more data elements of an input data entity. Decoding by a given one of the plurality of address decoder elements serves to conditionally activate the address decoder element depending on a function of values of the one or more data elements of the input data entity mapped to the one or more input address connection(s) and further depending on an activation threshold. Memory access operations to one of the plurality of storage locations are controlled by two or more distinct ones of the plurality of address decoder elements depending on coincidences in activation of the two or more distinct address decoder elements as a result of the decoding. A method and machine-readable instructions are also provided.

### BACKGROUND

Computer memory technology is constantly evolving to keep pace with present day computing demands, which include the demands of big data and artificial intelligence. Entire hierarchies of memories are utilised by processing systems to support processing workloads, which include from the top to the bottom of the hierarchy: Central processing Unit (CPU) registers, multiple levels of cache memory; main memory and virtual memory; and permanent storage areas including Read Only Memory (ROM)/Basic Input Output System (BIOS), removable devices, hard drives (magnetic and solid state) and network/internet storage.

In a computing system memory addressing involves processing circuitry such as a Central Processing Unit (CPU) or Graphics Processing Unit (GPU) providing a memory address of data to be accessed, which address decoding circuitry uses to locate and access an appropriate block of physical memory. The process is very similar whether the computing system be a server, desktop computer, mobile computing device or a System on Chip (SoC). A data bus of a computing system conveys data from the processing circuitry to the memory to perform a write operation, and it conveys data from the memory to the processing circuitry to perform a read operation. Address decoding is the process of using some (usually at the more significant end) of the memory address signals to activate the appropriate physical memory device(s) wherein the block of physical memory is located. In a single physical memory device (such as a RAM chip) a decode is performed using additional (usually at the less significant end) memory address signals to specify which row is to be accessed. This decode will give a “one-hot output” such that only a single row is enabled for reading or writing at any one time.

There is an incentive to improve the speed and efficiency of processing tasks and one way of achieving this involves providing fast and efficient memory and deploying memory hardware in an efficient way to support complex processing tasks, particularly those that involve processing high volumes of input data. Processing of high volumes of input data is common in fields including machine learning, robotics, autonomous vehicles, predictive maintenance and medical diagnostics.

### BRIEF INTRODUCTION OF THE DRAWINGS

Example implementations are described below with reference to the accompanying drawings, in which:

FIG. 1 schematically illustrates a data processing apparatus comprising a memory lattice for storing coincidences;

FIG. 2 schematically illustrates a two dimensional (2D) memory lattice having an address decoder per dimension, each address decoder comprising a plurality of address decoder elements to subsample an input data entity such as an image;

FIG. 3 schematically illustrates a set (or cluster) of input address connection connections of a single address decoder element of one of the address decoders of FIG. 2 showing mappings to six different pixel locations of an input image for performing subsampling of input data entities;

FIG. 4 schematically illustrates three different memory lattice locations (nodes) each activated by coincident address decoder elements and where a depth of storage units at each memory lattice location corresponds to a total number of classes;

FIG. 5 is a flow chart schematically illustrating initialisation of activation thresholds of address decoder elements of the memory lattice and assigning input address connection connections of address decoders element of each address decoder of the memory lattice to different subsamples of an input data entity representing an input image;

FIG. 6 is a flow chart schematically illustrating an unsupervised learning process for tuning a activation rate of address decoder elements of the memory lattice to be within a target activation rate (or range thereof) incorporating adjustments to input address connection characteristics such as longevities, polarities and weights and adjustments to activation thresholds triggering activation of address decoder elements;

FIG. 7 is a flow chart schematically illustrating a supervised learning process using class labels of a training data of input data entities set to populate class-specific storage locations at each storage location of the memory depending on coincident activations of address decoder elements of D different address decoders in a D-dimensional memory lattice;

FIG. 8 is a flow chart schematically illustrating an inference process to be implemented on a pre-trained memory lattice to predict a classification of a test image by determining a highest class count of coincidences previously stored at lattice memory locations; and

FIG. 9 is a graph schematically illustrating example simulation results obtained for an inference task performed on a computer memory pre-trained according to the present technique by sparsely populating memory locations depending upon the coincidental activation of pairs of address decoder elements of address decoders in a 2D lattice responsive to input of training data.

### DETAILED DESCRIPTION

According to the present technique, memory access operations are performed differently, which allows memory chips such as RAM chips to be more efficiently deployed to process data sets comprising large volumes of data and to extract characteristic information from those data sets. One potential application of this different type of memory access is machine learning. However, it has other applications in technology areas such as direct control of robots, vehicles and machines in general.

According to the present technique a memory is used to find coincidences between features found in entities (e.g. images or audio samples) of a training data set and to store the class of the training data entity at memory locations identified by those coincidences. This process is repeated for all entities in the training data set. Subsequently the class of a test data set entity is inferred by seeing with which class, the coincidences found in the test entity have most in common. This approach supports one-shot learning (where training involves only a single exposure to each training set data entity), greatly reducing training time and energy, and addresses a number of the other drawbacks of current machine learning techniques as described below.

The present technique performs memory accesses (read and write operations) in a new way and the way that the memory is accessed allows feature extraction from a data set to be efficiently automated, such that features of input data entities of a training data set are stored in memory by performing address decoding using samples of individual training data entities and storing data at particular locations in memory by activating memory locations for write operations depending on numerical values of the samples and corresponding activation thresholds. Information that is address decoded and written into the memory in this way may be used for subsequent inference to make predictions or to perform classification or to perform direct control.

Deep learning is a machine learning technique that has recently been used to automate some of the feature extraction process of machine learning. The memory access operations according to the present technique offer a new approach to automating the feature extraction process from a test data set that may be implemented energy efficiently even on general purpose computing devices or special purpose integrated circuits such as SoCs. Furthermore, once the memory according to the present technique has been populated by coincidences detected in a training data set, the same energy efficient processing circuitry may be used to implement an inference process, which is simple algorithmically relative to alternative techniques such as deep learning and thus can be performed more rapidly and energy efficiently and yet with good accuracy.

Machine learning, which is a sub-field of artificial intelligence, has technical applications in many different technology areas including image recognition, speech recognition, speech to text conversion, robotics, genetic sequencing, autonomous vehicles, fraud detection, machine maintenance and medical imaging and diagnosis. Machine learning may be used for classification or prediction or perhaps even for direct control of machines like robots and autonomous vehicles. There is currently a wide range of different machine learning algorithms available to implement for these technical applications such as linear regression, logistic regression, support vector machine, dimensionality reduction algorithms, gradient boosting algorithms and neural networks. Deep learning techniques such as those using artificial neural networks have automated much of the feature extraction of the machine learning process, reducing the amount of human intervention needed and enabling use of larger data sets. However, many machine learning implementations, including the most advanced available today are memory hungry and energy intensive, are very time consuming to train and can be vulnerable to “over-fitting” of a training data set meaning that inference to predict a class of test data can be prone to error. Furthermore the speed of inference to predict a class for test data using a pre-trained machine learning model can be frustratingly slow at least in part due to the complexity of the inference algorithms used. Related to this is the energy that may be used for inference as a result of the relatively large scale computing machinery appropriate to run these complex inference algorithms. As machine learning becomes more ubiquitous in everyday life, there is an incentive to find a machine learning classification or prediction techniques capable of at least one of: reducing training time of machine learning systems; reducing power consumption for training as well as for inference so that these computational tasks may be performed using general purpose processing circuitry in consumer devices or energy efficient custom circuitry such as a System on Chip (SoC); reducing demands of classification tasks on memory during inference; and providing more robustness against over-fitting in the present of noisy or imperfect input data. An ability to efficiently parallelise machine learning techniques is a further incentive. One potential application of the memory access according to the present technique is in the general field of artificial intelligence, which includes machine learning.

Although examples below show a memory lattice (or grid) having memory locations arranged in a regular structure similar to existing 2D RAM circuits, examples of the present technique are not limited to a lattice structure of storage locations and is not even limited to a regular structure of storage locations. The storage locations according to the computer memory of the present technique may be arranged in any geometrical configuration and in any number of dimensions provided that the storage locations are written to and read from depending in coincidences in activations of two or more different address decoder elements. The differences relating to the locations (and possibly values) of the data element(s) of the input data entities that are supplied as “addresses” for decoding by the address decoder elements.

Furthermore, although the examples below show D different address decoders being connected respectively to D different dimensions (e.g. 2 address decoders for 2 dimensions) of a lattice structure of memory locations, alternative examples within the scope of the present technique may implement a single address decoder to control memory access operations in more than one different dimension of a regularly arranged lattice of computer memory cells. For example a given address decoder element of a single address decoder could be connected to two different storage locations in different rows and different columns. Thus there is flexibility in how address decoder element can be connected to storage locations such that at least two different address decoder elements control access to a single storage location. According to the present technique, at least two different samples (such as pixel values) or groups of samples (where there is more than one input address connection to an address decoder element) can mediate read access or write access to a memory location and this can be implemented in a variety of alternative ways via computer memory geometries and address decoder connections. In some examples only a subset of address decoder elements that are connected to a given storage location may control access to that storage location. Thus some connections may be selectively activated and deactivated. Simple computer memory geometries in 2D are shown in the examples for ease of illustration.

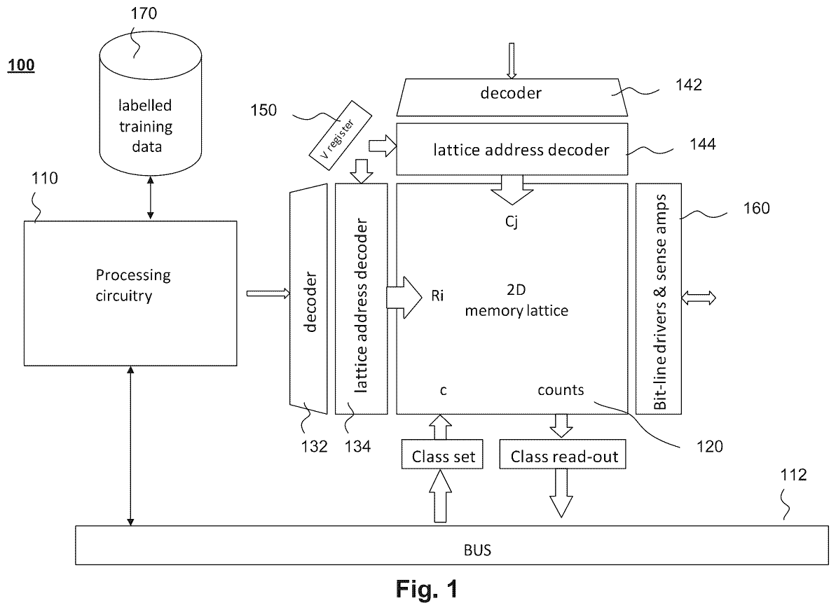

FIG. 1 schematically illustrates a data processing apparatus comprising a memory lattice for performing memory access operations. The memory access operations depend on a function of subsamples of an input data entity such as an image or an audio sample and further depending on a threshold. The apparatus 100 comprises a set of processing circuitry 110, a communication bus 112, a 2D memory lattice 120, a first address decoder 132, an address decoder for rows 134, a second address decoder 142, an address decoder for columns 144, a storage register 150, a set of bit-line drivers and sense amps 160 and a storage repository 170 for storing a set of labelled training data for training of the 2D memory lattice 120. The storage repository 170 may be remote from the other apparatus components and may be accessed via a computer network such as the Internet, for example.

The processing circuitry 110 may be general purpose processing circuitry such as one or more microprocessors or may be specially configured processing circuitry such as processing circuitry comprising an array of graphics processing units (GPUs). The first and second address decoders 132, 142 may each be address decoders such as the single address decoder conventionally used to access memory locations of a memory such as a Random Access Memory. The bus 112 may provide a communication channel between the processing circuitry and the 2D memory lattice 120 and its associated memory accessing circuitry 132, 134, 142, 144.

Memory arrays such as a RAM chip can be constructed from an array of bit cells and each bit cell may be connected to both a word-line (row) and a bit-line (column). Based on an incoming memory address the memory asserts a single word-line that activates bit cells in that row. When the word-line is high a bit stored in the bit-cell transfers to or from the bit-line. Otherwise the bit-line is disconnected from the bit cell. Thus conventional address decoding involves providing a decoder such as the address decoder 142 to select a row of bits based on an incoming memory address. The address decoder word lines (for rows) and bit lines (for columns) would be orthogonal in a conventional address decoding operation. The second address decoder 132 would not be needed to implement this type of address decoding. However, according to the present technique, memory access operations to memory locations in a d-dimensional memory lattice may controlled based on a function of d decoding operations. In this example one decoding operation indexes a row and another decoding operation indexes a column but memory access is mediated based on an outcome of both decoding operations, analogous to both the word line being activated by a first decoding and the bit-line of the lattice node being activated by a second decoding.

Each decoding operation is performed by an “address decoder element”, which is mapped to a plurality of samples (or subsamples) of an input data entity such as an image. The mapping may be formed based on a probability distribution relevant to at least one class of information for a given classification task. The samples may be drawn, for example, from specific pixel locations of a 2d image or voxel locations of a 3D image. The information of the input data entity may be converted to vector form for convenience of processing. The information may be any numerical data. Reading from or writing to the memory location of the memory lattice 120 depends on values of the plurality of samples via the decoding process. A function of the values for each address decoder element may be compared to an activation threshold to determine whether or not the address decoder element will fire (or activate) such that an address decoder element activation is analogous to activating a word-line or a bit-line. The memory access to a memory storage location (e.g. a lattice node) is permitted when the d address decoder elements that mediate access to that memory location all activate coincidentally. The activation threshold may be specific to a single address decoder element or may alternatively apply to two or more address decoder elements.

The first and second address decoders 132, 142 and the bit-line and sense amp drivers 160 may be utilised to set up and to test the 2D memory lattice 120. However, training of the 2D memory lattice 120 and performing inference to classify incoming data entities such as images is performed using the row and column address decoders 134, 144 and the register 150. The register 150 is used to hold a single training data entity or test data entity for decoding by the row and column address decoders 134, 144 to control access to memory locations at the lattice nodes.

To initialize the 2D memory lattice 120 ready for a new classification task, any previously stored class bits are cleared from the 2D memory lattice 120. To train the 2D lattice memory 120, for each training data entity in a given class “c”, any and all activated row Ri and column Cj pairs of the lattice have a class bit [c, i, j] set. The activation of a given address decoder element is dependent on decoding operations performed by the address decoders 134, 144. A row Ri is activated when a particular address decoder element of the row address decoder 134 mediating access to that memory location (in cooperation with a corresponding column address decoder element) “fires”. Similarly, a column Cj is activated when a particular address decoder element of the column address decoder 144 mediating access to that memory location “fires”. Determination of whether or not a given address decoder element should fire is made by address decoder element itself based on sample values such as pixel values of the input data entity currently stored in the register 150. The input data entity may be subsampled according to a particular pattern specified by the corresponding address decoder element. Each address decoder element evaluates a function of a plurality of pixel values of the input data entity and compares the evaluated function with an activation threshold. The function may be any function such as a sum or a weighted sum.

When the input data entity is a 2D image, the particular locations of pixel values of each input data entity used to evaluate the function are mapped to the address decoder element during a set up phase and the mapping may also be performed during an unsupervised learning phase (i.e. for which class labels are not utilised) when input address connections may be discarded and renewed. For example, where an n by m image is converted to a one dimensional vector having n by m elements, certain vector elements may be subsamples for each input image entity for a given address decoder element. Thus each address decoder element has a specific subsampling pattern that is replicated in processing of multiple input image entities. This allows “zeroing in on” particular image regions or audio segments that are information rich from a classification perspective in that they provide a good likelihood of being able to discriminate between different classes. This is analogous to distinguishing between a cat and a dog by a visual comparison of ears rather than tails, for example.

The 2D memory lattice of FIG. 1 performs machine learning inference based on a test image by counting the number of bits for all class bits identified by active (Ri, Cj) pairs that activate as a result of decoding the test image. The inferred class is the class with the highest bit count. To perform inference, the 2D memory lattice 120 is first trained using labelled training data to store class bits corresponding to memory locations where coincidental address decoder element activations occur. Once the memory lattice has been populated by storing class bits according to class labels of training data and by observing bit-line and word-line activation patterns for the training images then inference can readily performed by simply tallying up bit counts for activation patterns triggered by incoming test images. The simplicity of the inference affords power efficiency and makes inference relatively rapid in comparison to alternative machine learning techniques.

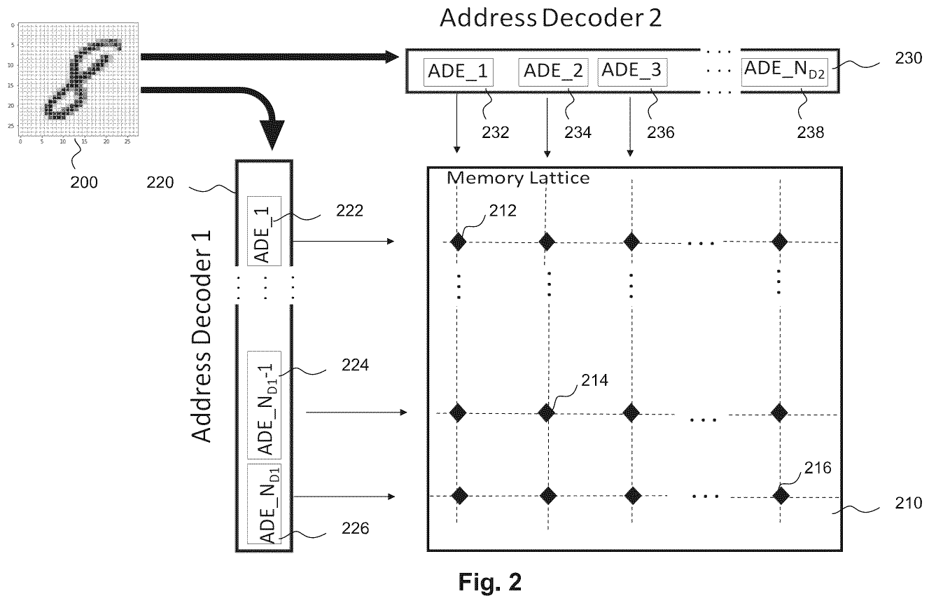

FIG. 2 schematically illustrates a two dimensional memory lattice 210 having an address decoder per dimension, each address decoder has a plurality of address decoder elements. As shown in FIG. 2, the memory lattice 210 comprises rows and columns of lattice nodes 212, 214, 216 forming a two-dimensional grid. A first address decoder 220 comprises a first plurality of address decoder elements 222, 224, 226 to control activation of rows of the memory lattice 210 whereas a second address decoder 230 comprises a second plurality of address decoder elements 232, 234, 236, 238 to controls activation of columns of the memory lattice 210. For example the first address decoder element 222 of the first address decoder 220 controls activation of a first row of the memory lattice based on decoding of a given number of pixel values of an input image that are mapped into a respective number of synaptic connections corresponding to the first address decoder element 222 for “decoding”.

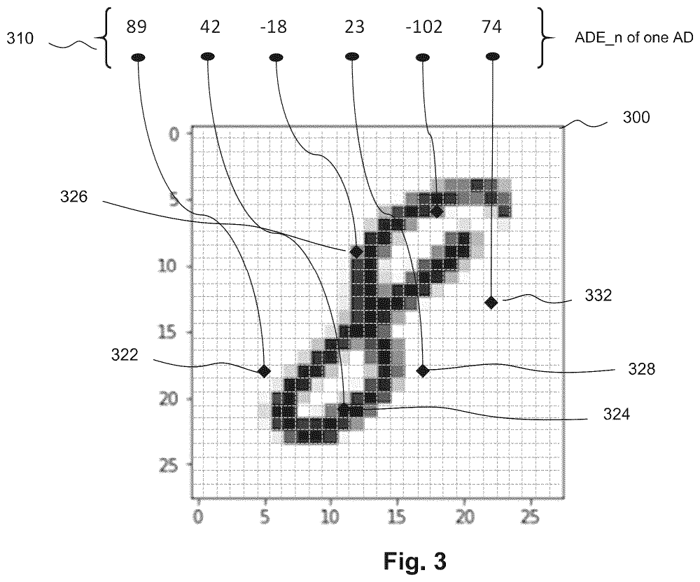

A decoding operation performed by a single address decoder element is schematically illustrated by FIG. 3 in which a feature vector 310 comprising six different synaptic connections each having an associated weight (the values 89, 42, −18 etc.) is evaluated by forming a sum of the products each of the six pixel values multiplied by their respective weights and comparing this sum of six products with an activation threshold value or target range of values associated with the particular address decoder element. The activation threshold associated with an address decoder element according to the present technique is analogous to an NMDA (N-methyl-D-aspartate) potential within a synaptic cluster within a dendrite in neuroscience. Neurons are brain cells having a cell body and specialised projections called dendrites and axons. Information flows between neurons via small gaps called input address connections. Dendrites bring information to a cell body across input address connections and axons take information away from the cell body. In the FIG. 3 example, each pixel of the subsample can be seen as part of a synaptic connection of a cluster of six synaptic connections of the given address decoder element. All input address connections of the cluster have inputs that contribute to determining whether or not the address decoder element should activate. Some input address connections may have larger relative contributions to reaching the activation threshold than others. The pixels making larger relative contributions are likely to be better choices for facilitating efficient discrimination between different information classes.

According to the present technique, an input address connection (counterpart of an input address connection) of an address decoder element of an address decoder of a memory lattice is a connection associated with an input such as a pixel position of an input image or a particular sample position in a time series of audio data or sensor data. The input address connection also has at least one further characteristic to be applied to the connected input sample such as a weight, a polarity and a longevity. The weights may differently emphasise contributions from different ones of the plurality of input address connections. The polarities may be positive or negative. The different polarities allow a particular data sample (data entity) to increase or decrease the address decoder element activation. For example, if the input data entity is a greyscale image and if the pixel luminance is between −128 (black) and +127 (white), a negative polarity may cause a black pixel to increase the likelihood of activation of an address decoder element mapped to that data sample whereas the negative polarity may cause a white pixel to decrease the likelihood of activation. A positive polarity could be arranged do the opposite. This helps, for example, in the context of an image recognition task to discriminate between a handwritten number 3 and a handwritten number 8, where the pixels illuminated in a 3 are a subset of those illuminated in an 8.

The longevities may be dynamically adapted as input data is processed by the memory lattice such that, for example, an input address connection whose contribution to an activation (i.e. activation) of an address decoder element is relatively large compared to the contributions of other input address connections of the same address decoder element has a greater longevity than an input address connection whose contribution to an activation of the address decoder element is relatively small compared to the other input address connections. Input address connection longevities, if present, may be initially set to default values for all input address connections and may be adjusted incrementally depending on address decoder activation events (activations) as they occur at least during training of the memory lattice and perhaps also during an inference phase of a pre-trained memory lattice.

A longevity threshold may be set such that, for example, if a given input address connection longevity falls below the longevity threshold value then the input address connection may be discarded and replaced by an input address connection to a different sample of the input data such as a different pixel position in an image or a different element in a one dimensional vector containing the input data entity. This provides a mechanism via which to evolve the memory lattice to change mappings of input data to progressively better synaptic connections to focus preferentially on input data features most likely to offer efficient discrimination between different classes of the input data.

In the FIG. 3 example, a product of a polarity and a weight is illustrated for each of the six synaptic connections. FIG. 3 shows an input image 300 of 28 by 28 pixels of 8-bit grayscale values and the input image contains a handwritten text character for classification. However, this is only one example for ease of illustration and the image could be, for example, a medical image for classification to assist with medical treatment or diagnosis or an image for assisting an autonomous vehicle with navigation of road conditions. Alternatively the image could be an image of sensor measurements related to a mechanical part to facilitate prediction and identification of any machine maintenance issues. Further examples of data types that could be input to the memory lattice for mapping to input address connections of the address decoder elements include video data, sensor data, audio data and biological data for a human or animal (e.g. genetic sequence data).

In the specific example of FIG. 3, a first input address connection has a weight of 89 and is connected to a pixel location 322 having (x,y) coordinates (5,18). A second input address connection has a weight of 42 and is connected to a pixel location 324 having (x,y) coordinates (11,21). A third input address connection has a weight of −18 and is connected to a pixel location 326 having (x,y) coordinates (12,9). A fourth input address connection has a weight of 23 and is connected to a pixel location 328 having (x,y) coordinates (17,18). A fifth input address connection has a weight of −102 and is connected to a pixel location 330 having (x,y) coordinates (23,5). A sixth input address connection has a weight of 74 and is connected to a pixel location 332 having (x,y) coordinates (22,13).

The feature vector 310 of FIG. 3 comprising the plurality (cluster) of synaptic connections may be used to evaluate a function of the input data samples associated with the synaptic connections depending on the input address connection characteristics such as weights and polarities and to compare the evaluated function with a activation threshold to conditionally activate the address decoder element, such as the address decoder element 222 of the first row of the memory lattice in FIG. 2.

For example if the function is a sum of products of the synaptic weights and the corresponding 8-bit values, taking account of the positive or negative polarity of each input address connection, a value of this sum may be compared with the activation threshold relevant to the address decoder element 222 and if (and only if) the sum is greater or equal to the activation threshold then the address decoder element 222 may activate (or equivalently fire). In particular, If on the other hand the weighted sum of products of input samples mapped to the feature vector 310 is less than the activation threshold, the address decoder element 222 may not activate in response to this input data item (an image in this example). The activation threshold upon which activation of the address decoder element 222 depends may be specific to the individual address decoder element 222 such that activation thresholds may differ for different address decoder elements in the same lattice memory. Alternatively, a activation threshold may apply globally to all address decoder elements of a given one of the two or more address decoders or may apply globally to address decoder elements of more than one address decoder. In a further alternative the activation threshold for the address decoder element 222 may be implemented such that it has partial contributions from different ones of the plurality of synaptic connections of the feature vector 310. The activation threshold(s) controlling activation of each address decoder element may be set to default values and dynamically adapted at least during a training phase of the memory lattice to achieve an activation rate within a target range to provide efficient classification of input data items.

Note from FIG. 2 that access to the lattice node 212 is controlled depending on simultaneous activation of the address decoder element 222 of the row and the address decoder element 232 of the column 232. Similarly, access to the lattice node 214 is controlled depending on simultaneous activation of the address decoder element 224 of the row and the address decoder element 234 of the column. It will be appreciated that a single address decoder could be used to mediate access to more than one dimension of the memory lattice. For example, an output of the address decoder element 232 could be arranged to control access to each of a row and a column of the lattice memory by appropriately wiring its output or configuring it in software. In this case two distinct address decoder elements, whether from the same address decoder or a different address decoder may be used to mediate access to a node of the 2D memory lattice.

The FIG. 3 example shows a feature vector 310 representing synaptic connections to six different input image pixels of an input item for a given address decoder element 222. In other examples, the number of synaptic connections for a synaptic cluster of an address decoder element may be greater than six or fewer than six. Furthermore, in some alternative examples, the number of synaptic connections may differ between different address decoders and even between different address decoder elements of the same address decoder.

Evaluation of the function of the feature vector 310 and comparison of this evaluated function with the relevant threshold could in principle activate the entire first row of the memory lattice 210.

However, according to at least some examples of the present technique, activation of a row of the memory lattice 210 is not sufficient to perform a memory access operation such as a memory read or a memory write. Instead, a memory access operation to a given lattice node 212 is dependent on a coincidence in activation of both the address decoder element 222 controlling the row and the address decoder element 232 controlling the column associated with the given lattice node 212. The same is true for each lattice node of the 2D memory lattice 210. The address decoder element 232 has a feature vector similar to the feature vector 310 of FIG. 3, but is likely to have synaptic connections to different pixel positions of the same input image 300 and thus the specific 8-bit pixel values used to evaluate the activation function may be different. Similarly the input address connection characteristics (e.g. weights, polarities, longevities) of a feature vector corresponding to the column address decoder element 232 are likely to differ from those of the feature vector 310. To allow memory access operations to the memory lattice node 212, the address decoder element 222 and the address decoder element 232 are both activated coincidentally, which means that they both activate based on evaluation of a given input data entity such as a given image.

However, in alternative examples coincidental activation could mean that each address decoder element is activated based on evaluation of say six different sample positions in a time series of measurements of a given input audio sequence. Thus it will be appreciated that coincidental activation is not necessarily coincidental in real time for input data items other than image data. Input data entities for processing by the address decoders of the present technique may comprise any scalar values. An audio stream could be divided into distinct audio segments corresponding to distinct input data entities and the memory lattice could decode, for example, individual vectors containing distinct audio sample sequences, such that different input address connections are connected to different one dimensional vector elements of a given audio segment. This may form the basis for voice recognition or speech to text conversion for example. In yet a further example an input data entity could comprise an entire human genome sequence or partial sequence for a given living being or plant. In this example different input address connection connections could be made to different genetic code portions of a given individual, animal or plant. The base pairs of the genetic sequence could be converted to a numerical representation for evaluation of the address decoder element function. Thus the coincidental activation in this case could relate to coincidences in activation of address decoder elements each mapped to two or more different genetic code portions at specific chromosome positions. Thus, according to the present technique, access to a memory location corresponding to a lattice node to read data from or to store data to that particular node depends on coincidences in activations of d address decoder elements in a d-dimensional lattice.

When the memory lattice comprises more than two dimensions, such as three dimensions for example, access to a memory location may depend on coincidental activation of three different address decoder elements. These three different address decoder elements may in some examples correspond respectively to an address decoder in the x dimension, an address decoder in the y dimension and an address decoder in the z dimension. However, other implementations are possible such as using three different address decoder elements of the same address decoder to mediate access to a single node of a 3D memory lattice. A single address decoder may be used to control access to more than one dimension of a given memory lattice or even to control access to memory nodes of more than one memory lattice. Where the same address decoder is used to control access to two or more lattice dimensions, some of the address decoder element combinations may be redundant. In particular lattice nodes along the diagonal of the 2D lattice will indicate coincidental activation based on the same cluster of synaptic connections and combination of address decoder element pairs in the upper diagonal each have a matching pair although in a reversed order (row i, column j) versus (column j, row i). Thus the number of unique coincidental activations is less than half what it would be if one address decoder was mapped to rows and a second different address decoder was mapped to columns.

The present technique includes a variety of different ways of mapping a given number of address decoders to memory lattices of different dimensions. Indeed combinations of two or more different memory lattices can be used in parallel to store and read class information for a given classification task. In three dimensions, D1, D2 and D3, three different two-dimensional memory lattices may be formed such that: a first memory lattice is accessed based on coincidences of address decoder D1 and address decoder D2; a second memory lattice is accessed based on coincidences in address decoder D2 and D3; and a third memory lattice is accessed based on coincidences in address decoder D1 and D3. Class information written into each of the three 2D memory lattices may be collated to predict a class of a test image in a pre-trained memory lattice of this type. In general with more than two address decoders multiple two dimensional memory lattices can be supported in a useful way to store and to read class information.

With four different address decoders, different combinations of lattice memories could be indexed. In particular the 4 address decoders could index: up to four different 3D lattice memories (i.e. 4=C(4,3) or 4 choose 3 in combinatorics); or up to six 2D lattice memories (6=C(4,2)) without using the same address decoder twice on any memory

Including coincidences within a single address decoder and taking the example of four different address decoders being used to control access to multiple two dimensional memory lattices, the total number of matrices to capture all of the possible activation coincidences is C(4,2)=6 plus four matrices for each of the four different lattice memories activated by the same address decoder on both rows and columns, giving a total of 10 matrices to capture 2D coincidences for four address decoders. For five different address decoders the total number of 2D matrices would be C(5,2)+5=10+5=15 matrices. Including the 2D memory lattices activated along both of the 2D by the same address decoder allows as much coincidence information as possible to be extracted from a given number of address decoders.

In hardware implementations of the address decoders such as the implementation illustrated by FIG. 1, it is convenient for a given address decoder to serve a single lattice memory, although the same address decoder can be duplicated exactly on a different lattice memory. In a software implementation (or possible a different hardware form) a single address decoder can readily serve multiple different memory lattices.

The use of coincidences in activations of address decoder elements corresponding to different subsampling patterns based on the mapping of clusters of input address connections associated with each address decoder element to different input data entity locations (such that each input address connection cluster performs a different sparse subsampling of an input data entity) allows the classification according to the present technique to be efficiently and accurately performed via focussing on a search for specific combinations of occurrences of certain representative features in each input data entity. This means that the classifier is less likely to be overwhelmed in a sea of information by seeking distinguishing characteristics by analysing every detail of the input data entity. Furthermore, the input address connection characteristics such as the pixel positions or input vector elements that input address connection clusters of each address decoder element are mapped to and also input address connection longevities and polarities can be dynamically adapted at least during a training phase to home in on features of the input data most likely to provide a good sparse sample for distinguishing between different classes.

In one example, classifying an input handwritten image character based on training the memory lattice using a training data set such as the Modified National Institute of Standards and Technology (MNIST) database might result in homing in on pixel locations of handwritten characters to sample such that the samples feeding an input address connection cluster are more likely to derive from an area including a part of the character than a peripheral area of the image with no handwritten pen mark. Similarly, homing in on pixel locations in an image more likely to reveal differences in similar characters such as “f” and “t” via the dynamic adaptation process of adjusting longevities and input address connection characteristics including input address connection mappings to pixel locations is likely to result in more accurate and efficient information classification. In this case the pixel locations at the bottom of the long stalk of the f and the t might provide a fruitful area to readily discriminate between the two characters.

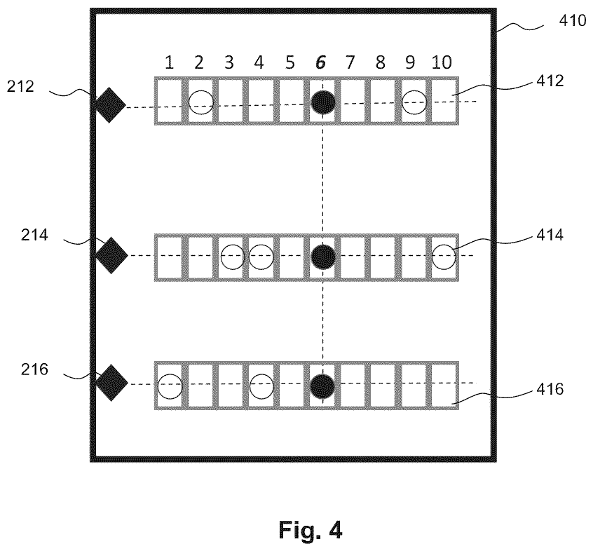

FIG. 4 schematically illustrates an arrangement 410 for storing class information in relation to a total of ten possible information classes (in this example) for three representative nodes 212, 214, 216 of the two dimensional lattice memory 210 of FIG. 2. The class information can be viewed as a “depth” for each lattice node equal to a total number of distinct information classes such that each level through the lattice node depth corresponds to a respective different one of the distinct information classes. Although only three lattice nodes 402, 404, 406 are represented, a lattice node depth may be present for a different subset of lattice nodes or, more likely, for all lattice nodes. A first set 412 of ten bit cells corresponds to the lattice node 212 of FIG. 2; a second set 414 of ten bit cells corresponds to the lattice node 212 of FIG. 2; and a third set of ten bit cells 416 corresponds to the lattice node 216 of FIG. 2. In this example a technique known as “one hot encoding” is used, which allows ten distinct information classes to be represented by 10 bit cells for a given lattice node. In machine learning one hot encoding may be used to convert categorical data such as red, green and blue into numerical data because numerical data are easier for machine learning algorithms to process. The categorical data is first defined using a finite set of label values such as “1” for red, “2” for green and “3” for blue. However, since there is no ordinal relationship between the colours red, green and blue, using these integer labels could lead to poor machine learning performance and so a one-hot encoding is applied to the integer representation in which a binary value is assigned to each unique integer value. For three colour categories three binary variables may be used so that red is 100, green is 010 and blue is 001. There are other ways of encoding categorical data corresponding to information classes and any such encoding may be used in examples of the present technique, but one-hot encoding is conveniently simple and thus has been used for illustration in the FIG. 4 example. FIG. 4 shows three bits corresponding to class 6 having been set as a result of memory node positions 212, 214 and 216 being coincidentally activated by an input data entity most recently processed by the address decoders of the memory lattice. The activation of lattice node 212 resulted from both row address decoder element 222 and column decoder element 232 having evaluated their characteristic function to be greater than or equal to the relevant activation threshold(s).

The activation of lattice node 214 resulted from both row address decoder element 224 and column decoder element 234 having been evaluated to be greater than or equal to the relevant activation threshold(s). The activation of lattice node 216 resulted from both row address decoder element 226 and column decoder element 238 having been evaluated to be greater than or equal to the relevant activation threshold(s). Thus the setting of the three class bits for class 6 was a result of coincidences in activation (activation) of three different pairs of address decoder elements corresponding respectively to the three different node locations. The memory lattice also has class bits of the depth that were set previously based on other coinciding activations of address decoder elements relevant to the lattice nodes.

In particular, lattice node 212 has bits corresponding to class 2 and class 9 set by previous decoding events of training data entities, lattice node 214 has bits corresponding to classes 3, 4 and 10 already set by previous decoding events of training data entities and lattice node 216 has bits corresponding to classes 1 and 4 already set by previous decoding events of training data entities.

Memory access operations comprise reading operations and writing operations. Writing to the memory lattice 212, 410 involves visiting all activated lattice nodes and setting the relevant class bits if they have not already been set. This may be performed as supervised training using class information available for each entity of a training data set. Reading from the memory lattice involves counting bits set across all activated memory positions for each class and choosing a class with the highest sum. The reading operations are performed in an inference phase after the memory lattice has already been populated by class information from a training data set. A test image fed into the memory lattice for decoding as part of an inference operation may then activate certain memory lattice nodes based on image pixel values to which the decoder input address connections are currently mapped. Historically stored class bits for each activated lattice node (only the lattice nodes actually activated by the test image) are then collated and counted such that the highest class count is a class prediction for the test image. This is analogous to classifying an image presented to a human based on a brain imaging pattern where, for example, a cat is known to trigger one characteristic brain activity pattern whereas a dog image is known to trigger another characteristic brain activity pattern based on activation of different coincidental combinations of synaptic clusters. Class prediction information of the test images in an inference phase may be written into the memory lattice in some examples. This may be appropriate where the prediction accuracy is known to be high and could be used to evolve the lattice memory perhaps resulting in further improved prediction performance.

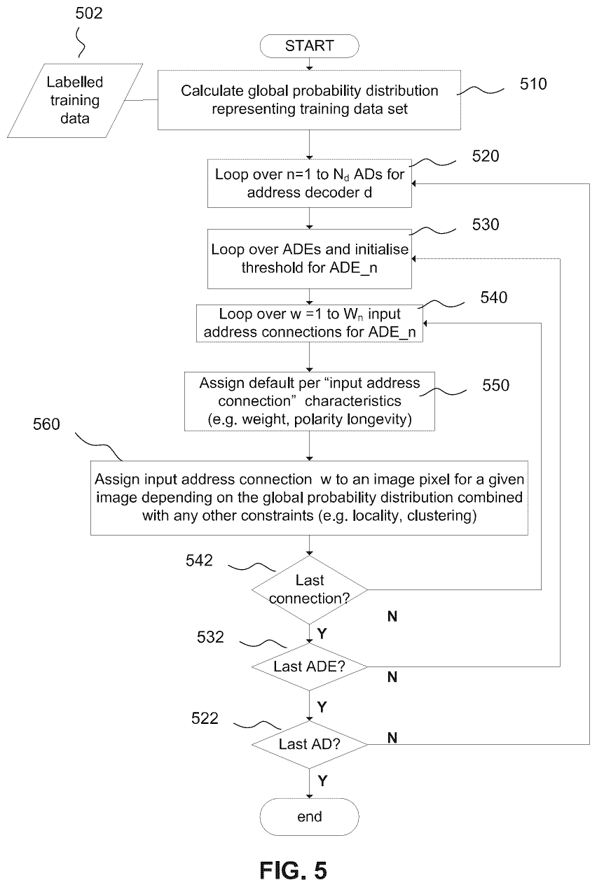

FIG. 5 is a flow chart schematically illustrating initialisation of activation thresholds and assigning input address connection connections for a memory lattice. The process starts and then at box 510 a set of labelled training data 512 is received, for example, from an external database, and a global probability distribution is formed to represent the training data set relevant to a given classification task. The labelled training data may be, for example image data such as medical image data, audio data, sensor data, genotype data or other biological data, robotics data, machine maintenance data, autonomous vehicle data or any other kind of technical data for performing a classification. In the example case of image data such as the image data of the FIG. 3 example, at box 510 a global probability distribution is calculated across all 784 pixels of the 28 by 28 pixel image 300. In this example the global probability distribution may be formed across say 60,000 input data entities (labelled training images) to form a global target distribution. This global target distribution may then be normalised to form a 784 dimensional categorical probability distribution. This categorical probability distribution is used to map input address connection clusters of individual address decoder elements to specific pixel positions of input images. In alternative examples, a target probability distribution may be formed for each class. However, at least in one implementation, the global target distribution has been found to be more effective. The mappings between input address connection clusters and the probability distribution may be performed in some examples using a technique such as Metropolis-Hastings sampling.

Once the global probability distribution has been calculated at box 510, the process comprises three nested loops in which an outermost loop at a box 520 loops over all n=1 to Na memory address decoders, where Na is at least two. A box 530 corresponds to a middle loop 530, which is a loop through each of multiple address decoder elements of a given address decoder. Part of the loop over the address decoder elements involves initialising an activation threshold (or “activation threshold”) for each address decoder element. The activation thresholds in this example are specific to the address decoder element, but they may be implemented differently such as by having an activation threshold common to all address decoder elements of a given address decoder. Different address decoders may have either the same number of or different numbers of constituent address decoder elements. Each address decoder element is analogous to a synaptic cluster within a dendrite and has a plurality (e.g. six) input address connections, each input address connection being associated with a pixel value of one of the input images and having one or more associated input address connection characteristics such as a weight, a polarity or a longevity. A box 540 corresponds to an innermost loop over each of a plurality of input address connections w=1 to Wₙ, for all input address connections in the cluster corresponding to the current address decoder element. The number of input address connections may be the same for each address decoder element of a given address decoder and may even be the same across different address decoders. However, in alternative examples, the number of input address connections per address decoder element may differ at least between different address decoders and this may allow more diversity in capturing different features of an input data entity.

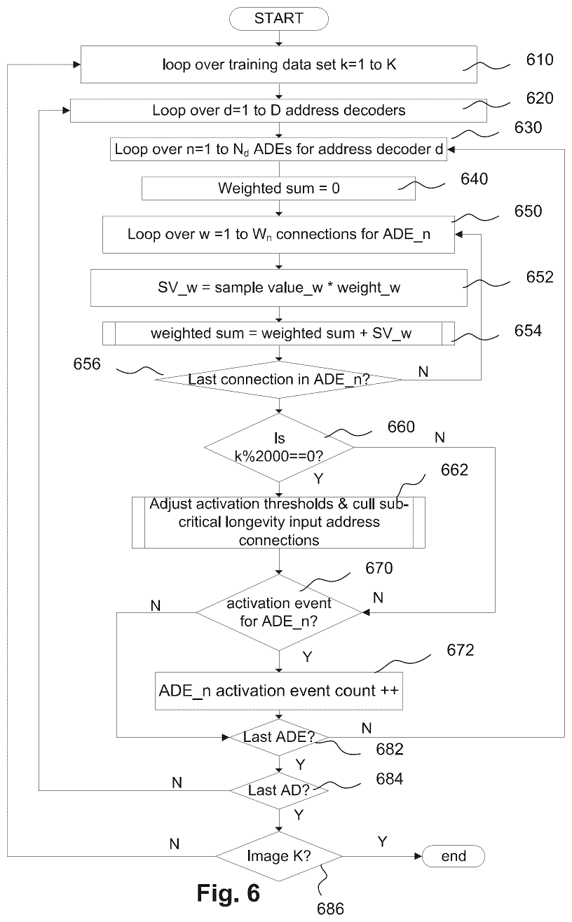

Within the three nested loops 520, 530, 540 a first process at a box 550 assigns default input address connection characteristics to initialise the computer memory prior to processing the labelled training data. Next at a box 560, each input address connection of each cluster is mapped to a feature (e.g. a pixel or a sample value) of an input data entity (e.g. an image) depending on the global probability distribution calculated at box 510. The mapping of input address connections to particular data entities may also take into account one or more additional constraint such as clustering, spatial locality or temporal locality. A decision box 542 terminates a loop over the input address connections when the last input address connection is reached. A decision box 532 terminates a loop over the address decoder elements when the last address decoder element of a current address decoder is reached. A decision box 522 terminates a loop over the address decoders when the last address decoder element is reached. Once the three nested loops have terminated the process ends and the lattice memory is then in a state where all address decoder elements have been appropriately mapped to specific features of input data entities, all of the address decoder element activation thresholds have been initialised and all default per input address connection characteristics have been initialised. Training of the computer memory (the “coincidence memory”) may then progress to a second unsupervised learning phase as illustrated in FIG. 6, during which activation thresholds and input address connection longevities are tuned using the training data set.

FIG. 6 is a flow chart schematically illustrating an unsupervised learning process for tuning a activation rate of address decoder elements to be within a target range of activation rates and the process also incorporates adjustments to input address connection characteristics such as longevities, polarities and weights. The process of FIG. 6 starts at box 610 with a loop over a training data set such as, for example, a set of around 60,000 (K=60,000) handwritten text characters. In some examples the training data set may be filtered to remove a subset of training images such as any defective images prior to undertaking the unsupervised learning. The loop over the training data set may be performed in order or training images may be drawn randomly from the training data set. Alternatively, subsets of the training set may be processed incrementally.

Similarly to the FIG. 5 process, in FIG. 6 there are three nested loops including an outer loop over d=1 to D address decoders at box 620, a middle loop at box 630 over all address decoder elements of the current address decoder and an inner loop at box 650 over all input address connections of a current address decoder element, which correspond to a input address connection cluster. In FIG. 6, the process starts and then prior to entering the loop 610 over the training data the activation event count specific to each address decoder element is initialised to zero. At box 640, prior to entering the loop 650 over the input address connections, a weighted sum is initialised. For each address decoder element, a loop over the corresponding input address connection cluster (set of connections) is performed to calculate a function of values to which the input address connection cluster is mapped in the current training data entity. In this example a sum is calculated of a product of an 8-bit pixel values associated with a given input address connection and a characteristic weight associated with the same input address connection. The product for an individual input address connection is calculated at box 652. At box 654 a weighted sum of pixel values is accumulated to obtain a weighted sum for the current address decoder element. At 656 it is determined whether or not all input address connections of a current address decoder element have been processed in calculation of the weighted sum. If the last input address connection has not been reached then the process cycles back to box 650 to process the next input address connection but if the last input address connection off the address decoder element has been reached then the process proceeds to 660 and subsequent boxes where the activation event count is incremented (if appropriate). A activation event count for the current address decoder element may be written to memory for the purpose of tracking activation rates at a per address decoder element level and to facilitate dynamic adaptation of the per address decoder element activation rates.

At box 660 a determination is made as to whether or not a given number of training data images have been cycled through. In this example, a determination at box 660 is whether or not a multiple of 2000 training images has been processed. If k is not exactly divisible by 2000 at decision box 660 then the threshold and longevity adjustment process is bypassed and the process proceeds directly to decision box 670.

If on the other hand k is exactly divisible by 2000 at decision box 660, then the process proceeds to process 662 where activation thresholds of individual address decoder elements may be adjusted to achieve the target activation rate for the given address decoder element.

Furthermore, also at box 662, all synaptic longevities are checked to determine whether or not they fall below a longevity threshold representing a minimum acceptable longevity. Any input address connections whose current longevity falls below the minimum threshold are culled and replaced by repeating the input address connection assignment process of box 560 of FIG. 5 to assign those input address connections to different pixel locations. This remapping of input address connections whose longevities fall below a minimum threshold provides an adaptation that eliminates sampling of pixels of an input image that are less likely to provide good discrimination between different classes of input data. For example, this would be true of pixel positions at the periphery of an image, which are less likely to include information.

The target activation rate or range of activation rates may differ in different examples, but in one example the target activation range is around 5% or less of the address decoder elements being activated. This target activation rate can be tracked and adjusted for globally across the memory lattice for each of the two or more memory lattice dimensions. Then the process proceeds to box 670 to determine whether or not an address decoder element activation event has occurred. If no activation event occurs at box 670 then the process goes to decision box 682 to determine if the loop over all of the address decoder elements has reached the end. If on the other hand a activation event has in fact occurred at decision box 670 then the process proceeds to box 672 where the activation event count for the current address decoder element is incremented and the longevities of the input address connections are dynamically adapted. The address decoder element activation event counts are accumulated over 2000 training data set input data entities (e.g. 2000 images) until k % 2000==0. This is only one example implementation and different examples may accumulate over a number of data entities different from 2000. The activation counts may be stored individually per address decoder element.

The longevities per input address connection may be adjusted in any one of a number of different ways, but in one example a simple Hebbian learning mechanism per input address connection is implemented within each input address connection cluster such that if the address decoder element corresponding to the input address connection cluster (i.e. two or more connections) activates then the input address connection of the cluster that is the smallest contributor to the sum which led to the activation threshold being crossed has its longevity characteristic decremented by one whereas the input address connection of the cluster which was the largest contributor to the activation threshold being crossed has its characteristic longevity incremented by one.

After incrementing the per address decoder element activation count at box 672, the process proceeds to a box 682 and checks if the current address decoder element is the last one in the current address decoder and if not cycles back to the next address decoder element at box 630. If the last address decoder element has been processed then box 684 is entered to check if the last address decoder has been reached. If there is a further address decoder then the process cycles back to the loop over address decoders at box 620. If the last address decoder has been reached at box 684 then a check is made at box 686 as to whether all of the images of the training data set have been cycled though. If the last training image k=K has been processed then the process ends, but otherwise it returns to box 610 and processes a further training image of the available set.

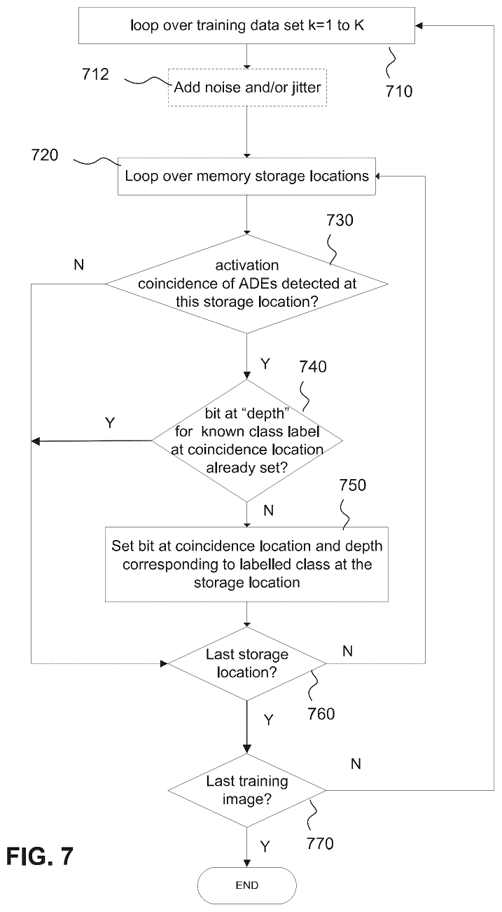

The processes of FIG. 5 and FIG. 6 each use the training data set to implement training phases of the memory lattice, but neither process uses any class labels of the training data set and thus they both correspond to unsupervised training phases. However, the FIG. 7 is a further training phase and this third phase does uses class labels of the training data set to populate the memory lattice with class information. Thus the FIG. 7 process can be viewed as a supervised training phase.

FIG. 7 is a flow chart schematically illustrating a supervised learning process using class labels of the training data set to populate class-specific storage locations at each node of the memory lattice depending on coincident activations of d different address decoders of one or more address decoder element for a d-dimensional memory lattice. The FIG. 7 memory lattice population process begins at box 710 where a loop over the training data set is performed. If there is a total of K training images then the loop is from 1 through to K. The appropriate number of training images to populate the coincidence memory may vary depending on a classification task to be performed. For the handwritten character image recognition training class of one example, 60,000 training images were used. Population of the lattice may use only a subset of the available training data entities (e.g. images or audio segments or genetic sequence data sets). The target address decoder element activation rate (or range of rates) is also likely to influence a lattice memory occupancy level after supervised learning.

At box 712 an optional process may be performed of adding at least one of noise and jitter to a training data entity. Adding at least one of noise and jitter to the training images can help to reduce or regularise over-fitting and can ameliorate any degradation of inference performance in the presence of imperfect input data entities received for classification. Within the loop over the training data set at 710 and after the noise/jitter addition (if implemented), a loop over memory storage locations is performed at box 720 for the entire memory. In some examples there may be more than one set of storage locations (e.g. two or more memory lattices) to process such as when three different address decoders are implemented using three or more distinct 2D dimensional memory lattices as discussed earlier in this specification. In a 2D memory lattice, coincidental activations of two address decoder elements control access to each lattice node. In a three dimensional memory lattice, coincidental activations of three address decoder elements control access to each lattice node and in a d dimensional lattice, coincidental activations of d address decoder elements control access to a memory node.

At box 730 a decision is made as to whether or not there are coincidental activations detected at the storage location for a given input training image, such as two coincidental address decoder element activations of the corresponding address decoder elements in a 2D memory lattice or storage location controlled by two address decoder elements for the purposes of memory access. If a coincidental activation does occur at the current memory location, then if one-hot encoding is implemented as in the FIG. 4 example, a class label of the training data image is used to set a class bit at the storage location at a “depth” corresponding to the class label at box 750. The setting of the class bits in this example is performed depending on coincidental activation of the two or more address decoder elements controlling access to the corresponding storage location. Each activation may depend on evaluation of a characteristic function for the address decoder element exceeding an activation threshold. In alternative examples when a coincident activation occurs for a given storage location in memory, the setting of the class bit may be performed with a given probability (rather than invariably if the class bit has not previously been set) in the range (0,1) for example. The probabilistic setting may be performed depending on a pseudo-random number. The probability may be applied in the same way to all classes or may alternatively be a class-dependent probability. The probability may also or alternatively be dependent on an amount by which the corresponding activation threshold is exceeded.

, Considering the example illustrated in FIG. 7, the setting of the class bit in the storage location is only performed depending on an outcome of a check at box 740 as to whether or not the class bit at that node at the relevant class depth has already been set. This bit may have already been set when a previous training image was processed. If the class bit for the activation coincidence has already been set then no writing operation is performed, but instead the box 750 is bypassed and the process proceeds to a decision box 760 and progresses with the loop over memory storage locations.

However, if the class bit has not been set previously then a writing operation is performed to set the class bit at box 750 and then the process advances to the decision box 760 to loop over any remaining storage locations. If the last storage location is determined to have been reached at decision box 760 then the process proceeds to a further decision box 770 to determine if the last training image in the set has been processed. If not then the process proceeds to box 710 to process the next training image. Otherwise the process ends.

At the end of the FIG. 7 process, the coincidence memory has been populated with class information based on training data and thus has been fully trained and is in a state appropriate for performing inference. In one example, where training was performed with MNIST training images and where information for ten different classes was stored, a memory occupancy after training was in the approximate range of 10% to 30% with a target address decoder element activation rate of 1% to 3% sparsity. In the case of 30% occupancy this would correspond to 3% occupancy for each of the ten classes and thus takes into account the class depth dimension as illustrated in FIG. 4.

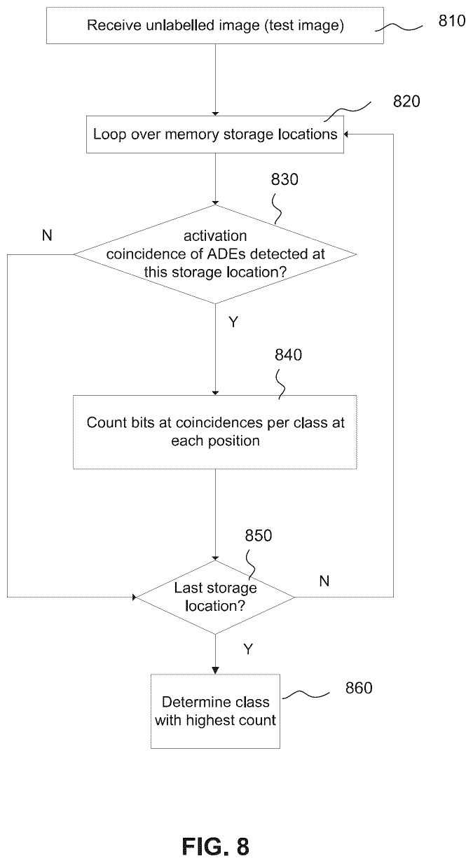

FIG. 8 is a flow chart schematically illustrating an inference process to be implemented on a pre-trained coincidence memory. At box 810 an unlabelled test image is received by the pre-populated coincidence memory. At box 820, a loop is performed over all memory locations and at box 830 a determination is made as to whether or not there is a coincidental activation of two or more address decoder elements controlling access to the current storage location. If at box 830 it is determined that there is no coincidental activation of the address decoder elements controlling access to the given storage location then the process proceeds to box 850 to determine if a loop over all storage locations of the coincidence memory is complete. If the loop over all storage locations is not complete then the process goes to box 820 to loop over the next storage location.

If at box 830 it is determined that there has been a coincidental activation of address decoder elements controlling the current storage location then the process proceeds to box 840 where any class bits set at any one or more of the ten different class depths (see FIG. 4) are determined and class counts for the test image are incremented for each class for which a class bit has been set at this location during pre-population of the lattice memory. This class count tally is performed for each storage location where the test image triggers a coincidental activation of address decoder elements so that when all of the storage locations have been tallied there will be a running count for each of the ten classes of which class depth bits were set during the pre-population of the coincidence memory in the storage locations that activated as a result of decoding the test image. In alternative examples the class count may be other than a simple tally of the class having the highest number of bits set, but may be a function of the class counts such as a linear or non-linear weighting of the class counts.

If the last memory storage location is determined to have been reached at decision box 850, the process proceeds to box 860 where all of the class depth bits that were pre-stored during population of the coincidence memory using the training data and where the storage location was activated by address decoder element activation coincidences using the test image are collated to establish a class having a highest bit count, which gives a prediction for the class of the test image. This is perhaps analogous to similar images triggering neuron activation activity in the same or a similar pattern of brain regions when two brain scans are compared. Note that in examples where multiple different memory lattices (or other multiple memory banks) are used to store class information for a given classification task, the class count tally is performed to include all set bits at all storage locations of each of the memory components.

FIG. 8 is an example of an inference process. In some cases, during use of the pre-trained computer memory for inference, one or more class bits already populating the memory may be removed (or unset). This class bit removal may be performed probabilistically (e.g. by generating a pseudo-random number). The class bits may be removed preferentially from certain memory locations. In examples where some class bits are deleted during the inference process the rate of removal of class bits may be at least approximately matched to a rate of new class bits being set during inference so as to maintain an at least approximately stable rate of occupancy of the memory. In examples such as this training of the computer memory and inference may be happening contemporaneously or such that the two processes are interleaved. This is in contrast with the distinct one-time consecutive phases as described in the flow charts of FIGS. 5 to 8.

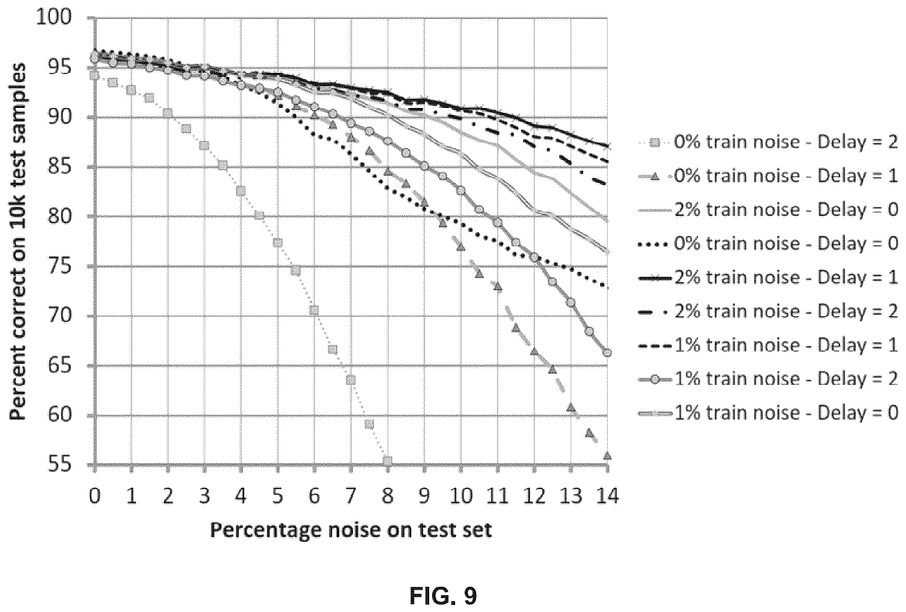

FIG. 9 is a graph schematically illustrating example simulation results obtained for an inference task performed on a computer memory pre-trained according to the present technique. Storage locations in the computer memory were populated depending upon the coincidental activation of pairs of address decoder elements of address decoders in a 2D lattice responsive to input of training data of a training data set. Inference was subsequently performed on a test data set to determine an accuracy of the prediction of image class.

The computer memory used to generate the results of FIG. 9 was similar to the 2D lattice illustrated in FIGS. 1, 2 and 4. The computer memory implemented address decoders and address decoder elements with adaptive thresholds and stored occurrences of binary coincidences activations of address decoder elements. Similarly to FIG. 4 and FIG. 7, the computer memory implemented one-hot encoding of class information. In the simulations greyscale images of handwritten characters were used for training and test images were used inference, as illustrated by FIG. 3.

In the FIG. 9 simulations the input pixels were binarized to be either 1 (above a threshold) or 0 and synapse weights were either +1 or −1. In some examples (Delay=1 and Delay=2) writing of a coincident activation of address decoder elements to a memory location was performed with a delay rather than being written probabilistically. For a Delay=2, a class bit would be written only after 2 previous occurrences of such a coincidence for which a write to memory was not performed. A Delay=0 corresponds to storage of a class bit corresponding to a coincidence upon first occurrence (detection) of the coincidence. The y-axis of FIG. 9 shows a % accuracy when inference is performed based on a computer memory pre-trained using a test data set comprising 10,000 greyscale images. Different amounts of noise (0%, 1% or 2%) were deliberately added during training. The X axis shows a percentage of noise deliberately applied to “test images” during an inference process in order to simulate imperfect inference. Both the noise on the training data and the noise on the test images used to perform inference were implemented by flipping pixels from 0 to 1 or vice versa.

From FIG. 9 it can be seen that in the absence of noise, around 96% to 97% inference accuracy has been achieved and the accuracy has even been observed up to 98% in other similar simulations. It can be seen that adding a small amount of noise and/or delay during training has very little impact when the noise on the test set (x-axis) is between about 0 to 5%. Thus machine learning inference performed by a computer memory trained according to the present technique produces a high accuracy of classification and furthermore is robust against noisy test input.

According to the present technique, a pre-trained machine learning model such as the computer memory populated by class information or prediction information representing coincidences in activations of two or more address decoder elements as a result of processing a set of training data may be encapsulated by a data set that facilitates replication of that pre-trained machine learning model on a different set of hardware. For example, the data set could be copied to another computer memory via a local network or downloaded to a processing circuitry such as an “Internet of Things” semiconductor chip or a microprocessor device to set up the computer memory ready to perform inference for a particular classification or prediction task. Such inference tasks may involve processing to perform inference on categories of data such as at least one of: sensor data, audio data; image data; video data; machine diagnostic data; biological data from a human, a plant or an animal; medical data from a human or animal; and technical data of a vehicle. The data set is for use by the processing circuitry and associated computer memory to implement the pre-trained machine learning model comprises data for replicating key characteristics of the pre-trained computer memory. This data set may include characteristic values associated with each address decoder element of the computer memory (e.g. activation thresholds and weights) and may further comprise data for storage at particular storage locations in the computer memory representing the occurrences of coincidences in activations of address decoder elements that were stored during the training process. Effectively, the data set is a blueprint for implementing a pre-trained machine learning model in a computer memory without having to perform the training.

In this specification, the phrase “at least one of A or B” and the phrase “at least one of A and B” and should be interpreted to mean any one or more of the plurality of listed items A, B etc., taken jointly and severally in any and all permutations.

Where functional units have been described as circuitry, the circuitry may be general purpose processor circuitry configured by program code to perform specified processing functions. The circuitry may also be configured by modification to the processing hardware. Configuration of the circuitry to perform a specified function may be entirely in hardware, entirely in software or using a combination of hardware modification and software execution. Program instructions may be used to configure logic gates of general purpose or special-purpose processor circuitry to perform a processing function.

Circuitry may be implemented, for example, as a hardware circuit comprising processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate arrays (FPGAs), logic gates, registers, semiconductor devices, chips, microchips, chip sets, and the like.

The processors may comprise a general purpose processor, a network processor that processes data communicated over a computer network, or other types of processor including a reduced instruction set computer RISC or a complex instruction set computer CISC. The processor may have a single or multiple core design. Multiple core processors may integrate different processor core types on the same integrated circuit die

Machine readable program instructions may be provided on a transitory medium such as a transmission medium or on a non-transitory medium such as a storage medium. Such machine readable instructions (computer program code) may be implemented in a high level procedural or object oriented programming language. However, the program(s) may be implemented in assembly or machine language, if desired. In any case, the language may be a compiled or an interpreted language, and may be combined with hardware implementations.

Embodiments of the present invention are applicable for use with all types of semiconductor integrated circuit (“IC”) chips. Examples of these IC chips include but are not limited to processors, controllers, chipset components, programmable logic arrays (PLAs), memory chips, network chips, and the like. In some embodiments, one or more of the components described herein may be embodied as a System On Chip (SOC) device. A SOC may include, for example, one or more Central Processing Unit (CPU) cores, one or more Graphics Processing Unit (GPU) cores, an Input/Output interface and a memory controller. In some embodiments a SOC and its components may be provided on one or more integrated circuit die, for example, packaged into a single semiconductor device.

The project leading to this application has received funding from the European Union's Horizon 2020 research and innovation programme under grant agreement No 650003.

The following examples pertain to further embodiments.

Example 1. Method for accessing data in a computer memory having a plurality of storage locations, the method comprising: mapping two or more different address decoder elements to a storage location in the computer memory, each address decoder element having one or more input address connection(s) to receive value(s) from a respective one or more data elements of an input data entity;
decoding by each of the mapped address decoder elements to conditionally activate the address decoder element depending on a function of the received values from the corresponding one or more input address connections and further depending on an activation threshold; and
controlling memory access operations to a given storage location depending on coincidences in activation, as a result of the decoding, of the two or more distinct address decoder elements mapped to the given storage location.

2. Method of example 1, wherein the threshold upon which the conditional activation of the given address decoder element depends is one of: a threshold characteristic to the given address decoder element; a threshold applying globally to a given address decoder comprising a plurality of the address decoder elements; and a threshold having partial contributions from different ones of the plurality of input address connections.

3. Method of example 1 or example 2, wherein each of at least a subset of the plurality of input address connections has at least one connection characteristic to be applied to the corresponding data element of the input data entity as part of the conditional activation of the given address decoder element and wherein the at least one input address connection characteristic comprises one or more of: a weight, a longevity and a polarity.

In some examples of example 3, the at least once connection characteristic comprises a longevity and wherein the longevity of the one or more input address connections of the given address decoder element are dynamically adapted during a training phase of the computer memory to change depending on relative contributions of the data elements of the input data entity drawn from the corresponding input address connection

4. Method of example 3, wherein the at least one connection characteristic comprises a longevity and wherein the longevity of the one or more input address connections of the given address decoder element are dynamically adapted during a training phase of the computer memory to change depending on relative contributions of the data elements of the input data entity drawn from the corresponding input address connection.

5. Method as in example 3 or example 4, wherein when the input data entity is at least a portion of a time series of input data and wherein a connection characteristic comprising a time delay is applied to at least one of the plurality of input address connections of the given address decoder element to make different ones of the samples of the time series corresponding to different capture times arrive simultaneously in the address decoder element for evaluation of the conditional activation.

6. Method of any one of the preceding examples, wherein the plurality of storage locations are arranged in a d-dimensional lattice structure and wherein a number of lattice nodes of the memory lattice in an i-th dimension of the d dimensions, where i is an integer ranging from 1 through to d, is equal to the number of address decoder elements in an address decoder corresponding to the i-th lattice dimension.

7. Method of any one of the preceding examples, wherein the input data entity corresponds to one of a plurality of distinct information classes and wherein the computer memory is arranged to store class-specific information indicating coincident activations at one or more of the plurality of storage locations by performing decoding of a training data set.

8. Method of example 7, wherein at least one of the plurality of storage locations has a depth greater than or equal to a total number of the distinct information classes and wherein each level through the depth of the plurality of storage locations corresponds to a respective different one of the distinct information classes and is used for storage of information indicating coincidences in activations relevant to the corresponding information class.

9. Method of example 8, wherein a count of information indicating coincidences in activation stored in the class-specific depth locations of the computer memory provides a class prediction in a machine learning inference process.

10. Method of example 9, wherein the class prediction is one of: a class corresponding to a class-specific depth location in the memory having maximum count of coincidences in activation; or determined from a linear or a non-linear weighting of the coincidence counts stored in the class-specific depth locations.

11. Method of any one of the preceding examples, wherein data indicating occurrences of the coincidences in the activations of the two or more distinct address decoder elements are stored in the storage locations in the computer memory whose access is controlled by those two or more distinct address decoder elements in which the coincident activations occurred and wherein the storage of the data indicating the occurrences of the coincidences is performed one of: invariably; conditionally depending on a global probability; or conditionally depending on a class-dependent probability.

In some examples the storage of the data indicating the occurrences of the coincidences depends on a function of an extent to which at least one of the activation thresholds associated with the coincidence is exceeded.

12. Method of any one of the preceding examples, comprising two different address decoders and wherein a first number of data elements, N_{D1}, of the input address connections supplied to each of the plurality of address decoder elements of a first one of the two address decoders is a different from a second number of input address connections, N_{D2}, supplied to each of the plurality of address decoder elements of a second, different one of the two different address decoders.

13. Method of any one of examples 1 to 12, wherein the function of values upon which the conditional activation of an address decoder element depends is a sum or a weighted sum in which weights are permitted to have a positive or a negative polarity.

14. Method of any one of the preceding examples, wherein the input address connections are set using at least one of: a probability distribution associated with an input data set including the input data entity; clustering characteristics of the input data set; a spatial locality of samples of the input data set; and a temporal locality of samples of the input data set. In some examples where the function is a weighted sum, the weights may comprise at least one positive weight and at least one negative weight.

In examples where the input data set is a training data set the probability distribution is either a global probability distribution across a plurality of classes associated with the input data set or a class-specific probability distribution

15. Method of any one of examples 1 to 14, wherein the input data entity is taken from an input data set comprising a training data set to which at least one of noise and jitter has been applied.

16. Method of any one of examples 1 to 15, wherein the input address connections are set using at least one of: a probability distribution associated with an input data set including the input data entity and wherein a selection of the one or more data elements from the input data set for a given input address connection based on the probability distribution is performed using Metropolis-Hastings sampling.

17. Method of any one of the preceding examples, wherein the input data entity is drawn from a training data set and wherein the activation threshold(s) of the address decoder elements of the one or more address decoder are dynamically adapted during a training phase to achieve a target address decoder element activation rate.

18. Method of any one of the preceding examples, wherein the input data entity comprises at least one of: sensor data, audio data; image data; video data; machine diagnostic data; biological data from a human, a plant or an animal; medical data from a human or animal; and technical data of a vehicle.

19. Method of any one of the preceding examples, wherein the input data entity is drawn from a training data set and wherein the computer memory is populated by memory entries indicating conditional activations triggered by decoding a plurality of different input data entities drawn from the training data set.

20. Method of example 19, wherein the populated computer memory is supplied with a test input data entity for classification and wherein indications of conditional activations previously recorded at one or more of the plurality of storage locations in the computer memory by the training data set are used to perform inference to predict a class of the test input data entity.

In some examples of the method, apparatus and computer program, the target address decoder element activation rate is a sparse activation rate of around 5%.

Apparatus features of the computer memory may implement the method of any one of the examples above.

21. Machine-readable instructions provided on a machine-readable medium, the instructions for processing to implement the method of any one of examples 1 to 20, wherein the machine-readable medium is a storage medium or a transmission medium.

Example 22 is computer memory apparatus comprising:
a plurality of storage locations;
a plurality of address decoder elements, each having a one or more input address connections for mapping to a respective one or more data elements of an input data entity;
wherein decoding by a given one of the plurality of address decoder elements serves to conditionally activate the address decoder element depending on a function of values of the one or more data elements of the input data entity mapped to the one or more input address connection(s) and further depending on an activation threshold; and
wherein memory access operations to one of the plurality of storage locations are controlled by two or more distinct ones of the plurality of address decoder elements depending on coincidences in activation of the two or more distinct address decoder elements as a result of the decoding.

Example 23 is a pre-trained machine learning model comprising the computer memory of example 22 or a pre-trained machine learning model trained using the method of any one of examples 1 to 20, wherein a computer memory implementing the pre-trained machine learning model is populated by coincidences activated by a set of training data.

24. The pre-trained machine-learning model of example 23, wherein one or more memory entries indicating a coincidence at the corresponding storage location is deleted from the computer memory when the pre-trained machine learning model is performing inference and wherein optionally the one or more memory entries deleted from the computer memory during the inference is selected probabilistically.

In some examples pre-trained machine learning model of example 24, a rate of deletion of memory entries deleted from the computer memory during the inference is arranged to at least approximately match a rate of adding new memory entries indicating coincidences as a result of decoding further input data entities on which the inference is being performed.

Example 25 is a machine-readable medium comprising a data set representing a design for implementing in a computer memory, a machine learning model pre-trained using the method of any one of examples 1 to 20, the data set comprising a set of characteristic values for setting up a plurality of address decoder elements of the computer memory and a set of address decoder element coincidences previously activated by a training data set and corresponding storage locations of the coincidental activations for populating the computer memory.

1-25. (canceled)

26. A method for accessing data in a computer memory having a plurality of storage locations, the method comprising:
mapping two or more different address decoder elements to a storage location in the computer memory, each address decoder element having one or more input address connection(s) to receive value(s) from a respective one or more data elements of an input data entity;
decoding by each of the mapped address decoder elements to conditionally activate the address decoder element depending on a function of the received values from the corresponding one or more input address connections and further depending on an activation threshold; and
controlling memory access operations to a given storage location depending on coincidences in activation, as a result of the decoding, of the two or more distinct address decoder elements mapped to the given storage location.

27. The method of claim 26, wherein the threshold upon which the conditional activation of the given address decoder element depends is one of: a threshold characteristic to the given address decoder element; a threshold applying globally to a given address decoder comprising a plurality of the address decoder elements; and a threshold having partial contributions from different ones of the plurality of input address connections.

28. The method of claim 26, wherein each of at least a subset of the plurality of input address connections has at least one connection characteristic to be applied to the corresponding data element of the input data entity as part of the conditional activation of the given address decoder element and wherein the at least one input address connection characteristic comprises one or more of: a weight, a longevity and a polarity.

29. The method of claim 28, wherein the at least one connection characteristic comprises a longevity and wherein the longevity of the one or more input address connections of the given address decoder element are dynamically adapted during a training phase of the computer memory to change depending on relative contributions of the data elements of the input data entity drawn from the corresponding input address connection.

30. The method of claim 28, wherein when the input data entity is at least a portion of a time series of input data and wherein a connection characteristic comprising a time delay is applied to at least one of the plurality of input address connections of the given address decoder element to make different ones of samples of the time series corresponding to different capture times arrive simultaneously in the address decoder element for evaluation of the conditional activation.

31. The method of claim 26, wherein the plurality of storage locations are arranged in a d-dimensional lattice structure and wherein a number of lattice nodes of a memory lattice in an i-th dimension of the d dimensions, where i is an integer ranging from 1 through to d, is equal to a number of address decoder elements in an address decoder corresponding to the i-th lattice dimension.

32. The method of claim 26, wherein the input data entity corresponds to one of a plurality of distinct information classes and wherein the computer memory is arranged to store class-specific information indicating coincident activations at one or more of the plurality of storage locations by performing decoding of a training data set.

33. The method of claim 32, wherein at least one of the plurality of storage locations has a depth greater than or equal to a total number of the distinct information classes and wherein each level through the depth of the plurality of storage locations corresponds to a respective different one of the distinct information classes and is used for storage of information indicating coincidences in activations relevant to the corresponding information class.

34. The method of claim 33, wherein a count of information indicating coincidences in activation stored in class-specific depth locations of the computer memory provides a class prediction in a machine learning inference process.

35. The method of claim 34, wherein the class prediction is one of: a class corresponding to a class-specific depth location in the memory having maximum count of coincidences in activation; or determined from a linear or a non-linear weighting of the coincidence counts stored in the class-specific depth locations.

36. The method of claim 26, wherein data indicating occurrences of the coincidences in the activations of the two or more distinct address decoder elements are stored in the storage locations in the computer memory whose access is controlled by those two or more distinct address decoder elements in which the coincident activations occurred and wherein the storage of the data indicating the occurrences of the coincidences is performed one of: invariably; conditionally depending on a global probability; or conditionally depending on a class-dependent probability.

37. The method of claim 26, comprising two different address decoders and wherein a first number of data elements, N_{D1}, of the input address connections supplied to each of the plurality of address decoder elements of a first one of the two address decoders is a different from a second number of input address connections, N_{D2}, supplied to each of the plurality of address decoder elements of a second, different one of the two different address decoders.

38. The method of claim 26, wherein the function of values upon which the conditional activation of an address decoder element depends is a sum or a weighted sum in which weights are permitted to have a positive or a negative polarity.

39. The method of claim 26, wherein the input address connections are set using at least one of: a probability distribution associated with an input data set including the input data entity; clustering characteristics of the input data set; a spatial locality of samples of the input data set; and a temporal locality of samples of the input data set.

40. The method of claim 26, wherein the input data entity is taken from an input data set comprising a training data set to which at least one of noise and jitter has been applied.

41. The method of claim 26, wherein the input address connections are set using at least one of: a probability distribution associated with an input data set including the input data entity and wherein a selection of the one or more data elements from the input data set for a given input address connection based on the probability distribution is performed using Metropolis-Hastings sampling.

42. The method of claim 26, wherein the input data entity is drawn from a training data set and wherein the activation threshold(s) of the address decoder elements of the one or more address decoder are dynamically adapted during a training phase to achieve a target address decoder element activation rate.

43. The method of claim 26, wherein the input data entity comprises at least one of: sensor data, audio data; image data; video data; machine diagnostic data; biological data from a human, a plant or an animal; medical data from a human or animal; and technical data of a vehicle.

44. The method of claim 26, wherein the input data entity is drawn from a training data set and wherein the computer memory is populated by memory entries indicating conditional activations triggered by decoding a plurality of different input data entities drawn from the training data set.

45. The method of claim 44, wherein the computer memory is supplied with a test input data entity for classification and wherein indications of conditional activations previously recorded at one or more of the plurality of storage locations in the computer memory by the training data set are used to perform inference to predict a class of the test input data entity.

46. A machine-readable instructions provided on a non-transitory machine-readable medium, the instructions for processing to implement the method of claim 26, wherein the machine-readable medium is a storage medium or a transmission medium.

47. A computer memory apparatus, comprising:
a plurality of storage locations; and
a plurality of address decoder elements, each having a one or more input address connections for mapping to a respective one or more data elements of an input data entity;
wherein decoding by a given one of the plurality of address decoder elements serves to conditionally activate the address decoder element depending on a function of values of the one or more data elements of the input data entity mapped to the one or more input address connection(s) and further depending on an activation threshold; and
wherein memory access operations to one of the plurality of storage locations are controlled by two or more distinct ones of the plurality of address decoder elements depending on coincidences in activation of the two or more distinct address decoder elements as a result of the decoding.

48. A pre-trained machine learning model using the method of claim 26, wherein a computer memory implementing the pre-trained machine learning model is populated by coincidences activated by a set of training data.

49. The pre-trained machine-learning model of claim 48, wherein one or more memory entries indicating a coincidence at the corresponding storage location is deleted from the computer memory when the pre-trained machine learning model is performing inference and wherein optionally the one or more memory entries deleted from the computer memory during the inference is selected probabilistically.

50. A non-transitory machine-readable medium comprising a data set representing a design for implementing in a computer memory, a machine learning model pre-trained using the method of claim 26, the data set comprising a set of characteristic values for setting up a plurality of address decoder elements of the computer memory and a set of address decoder element coincidences previously activated by a training data set and corresponding storage locations of the coincident activations for populating the computer memory.
